(19) United States
(12) Patent Application Publication
(10) Pub. No.: US 2014/0083482 A1
(43) Pub. Date: Mar. 27, 2014

(54) ARCHITECTURAL ARTICLE WITH PHOTOVOLTAIC CELL AND VISIBLE LIGHT-TRANSMITTING REFLECTOR

(71) Applicant: 3M INNOVATIVE PROPERTIES COMPANY, St.Paul, MN (US)

(72) Inventor: Timothy J. Hebrink, Scandia, MN (US)

(73) Assignee: 3M INNOVATIVE PROPERTIES COMPANY, SAINT PAUL, MN (US)

(21) Appl. No.: 14/116,674

(22) PCT Filed: May 9, 2012
(86) PCT No.: PCT/US12/37035

§ 371 Date: Nov. 8, 2013

Related U.S. Application Data
(60) Provisional application No. 61/484,068, filed on May 9, 2011.

(51) Int. Cl. H01L 31/0232; G02B 5/20; H01L 31/052

(52) U.S. Cl. CPC H01L 31/02325; H01L 31/0522; G02B 5/20
USPC 136/246; 136/257

(57) ABSTRACT

An architectural article that includes a photovoltaic cell and a visible light-transmitting reflector positioned to reflect light onto the photovoltaic cell is disclosed. The visible light-transmitting reflector includes a multilayer optical film having an optical stack with a plurality of alternating first and second optical layers having different indices of refraction. The multilayer optical film reflects at least a portion of light in a range of wavelengths that corresponds with the absorption bandwidth of the photovoltaic cell.

### CROSS REFERENCE TO RELATED APPLICATION

This application claims priority to U.S. Provisional Application No. 61/484,068, filed May 9, 2011, the disclosure of which is incorporated by reference in its entirety herein.

### BACKGROUND

It is known to install and/or integrate photovoltaic devices and systems into commercial and residential buildings. Such systems have generally been limited to conventional roof-top based systems that may have limited photovoltaic capability and little aesthetic appeal. Conventional roof-top based systems typically depend on racking systems, which typically are not suitable, for example, for integrating into a vertical building face in an attractive and convenient manner and may have limited suitability in other configurations also.

In concentrated photovoltaic applications, conventional solar concentrating mirrors are typically used to direct broad bandwidths of solar energy onto a photovoltaic cell or solar heat transfer element. However, electromagnetic radiation of certain wavelengths reflected from the solar concentrating mirror onto the solar element may adversely affect the solar element. For example, certain wavelengths in the infrared spectrum can cause certain photovoltaic cells to undesirably increase in temperature. As a result, the photovoltaic cells may lose efficiency and degrade over time due the excessive thermal exposure. Long term exposure to ultraviolet (UV) light also typically leads to premature degradation of components of the photovoltaic cell. Some solar concentrating mirrors that reflect wavelengths corresponding to the absorption bandwidth of a selected solar cell and either transmits or absorbs a major portion of light outside this bandwidth have been disclosed in Int. Pat. App. Pub. No. WO 2009/140493 (Hebrink et al.).

### SUMMARY

The present disclosure relates to an architectural article that includes a photovoltaic cell and a visible light-transmitting reflector. The visible light-transmitting reflector can be designed to concentrate a specific bandwidth of light onto a selected solar cell. The architectural article is typically suitable for integrating into a building or other structure. For example, the architectural article may be a window, a skylight, a covering or partial covering such as a roof or an awning, an atrium, a door, or a combination thereof. Advantageously, when the architectural article is installed as part of a building or structure, the visible light-transmitting reflector allows visible light to enter into the building or structure (that is, it allows daylighting). Depending on aesthetic requirements, the visible light-transmitting reflector may appear colorless or colored. In some embodiments, the visible light-transmitting reflector may appear to have a different color when viewed at a zero-degree viewing angle than when it is viewed off-angle.

In one aspect, the present disclosure provides an architectural article comprising a photovoltaic cell having an absorption bandwidth and a visible light-transmitting reflector positioned to reflect light onto the photovoltaic cell. The visible light-transmitting reflector includes a multilayer optical film having an optical stack with a plurality of alternating first and second optical layers with different indices of refraction. The multilayer optical film reflects at least a portion of light in a range of wavelengths that corresponds with the absorption bandwidth of the photovoltaic cell.

In this application:

Terms such as “a”, “an” and “the” are not intended to refer to only a singular entity, but include the general class of which a specific example may be used for illustration. The terms “a”, “an”, and “the” are used interchangeably with the term “at least one”.

The phrase “at least one of” followed by a list of two or more items refers to any one of the items in the list and any combination of two or more items in the list.

The term “light” refers to electromagnetic radiation, whether visible to the unaided human eye or not.

The term “polymer” refers to a macromolecular compound consisting essentially of one or more repeated monomeric units, or a mixture of macromolecular compounds that consist essentially of one or more like repeated monomeric units.

All numerical ranges are inclusive of their endpoints and non-integral values between the endpoints unless otherwise stated.

### BRIEF DESCRIPTION OF DRAWINGS

The disclosure may be more completely understood in consideration of the following detailed description of various embodiments of the disclosure in connection with the accompanying drawings, in which:

FIG. 1 is a schematic side view of an exemplary embodiment of an architectural article of the present disclosure installed as a covering for a structure;

FIG. 1a is a perspective view of an exemplary embodiment of an architectural article according to the present disclosure;

FIG. 2 is a schematic view of another exemplary embodiment of an architectural article of the present disclosure installed as a covering for a structure; and

FIG. 3 is a schematic view of yet another exemplary embodiment of an architectural article of the present disclosure installed as a covering for a structure.

### DETAILED DESCRIPTION

Architectural articles according to the present disclosure include a visible light-transmitting reflector that includes a multilayer optical film having an optical stack with a plurality of alternating first and second optical layers with different indices of refraction. Conventional multilayer optical films with alternating layers of at least one first polymer and one second polymer may be employed in creating the visible light-transmitting reflector. By selecting the appropriate layer pairs with appropriate refractive indices, the layer thickness, and/or the number of layer pairs, the optical stack can be designed to transmit or reflect desired wavelengths of light.

By appropriate selection of the first optical layers and the second optical layers, the reflector in the architectural article disclosed herein can be designed to reflect or transmit a desired bandwidth of light. Reflection is generated at each interface between optical layers in an optical stack, which layers have refractive indices that are different, n₁ and n₂, respectively. Light that is not reflected at the interface of adjacent optical layers typically passes through successive layers and is either absorbed in a subsequent optical layer, reflected at a subsequent interface, or is transmitted through the optical stack altogether. Typically, the optical layers of a given layer pair are selected such as to be substantially transparent to those light wavelengths at which reflectivity is desired. Light that is not reflected at a layer pair interface passes to the next layer pair interface where a portion of the light is reflected and unreflected light continues on, and so on. Increasing the number of optical layers in the optical stack may provide more optical power. In this way, an optical layer stack with many optical layers is capable of generating a high degree of reflectivity. For example, if the refractive index between the layer pairs is small, the optical stack may not achieve the desired reflectivity, however by increasing the number of layer pairs, sufficient reflectivity may be achieved. In some embodiments of the present disclosure, the optical stack comprises at least 2 first optical layers and at least 2 second optical layers, at least 5 first optical layers and at least 5 second optical layers, at least 50 first optical layers and at least 50 second optical layers, at least 200 first optical layers and at least 200 second optical layers, at least 500 first optical layers and at least 500 second optical layers, or at least 1000 first optical layers and at least 1000 second optical layers. In general, at least a portion of the first optical layers and at least a portion of the second optical layers are in intimate contact.

In general, the reflectivity of the interface of adjacent optical layers is proportional to the square of the difference in index of refraction of the first optical layer and the second optical layer at the reflecting wavelength. The absolute difference in refractive index between the layer pair (n₁-n₂) is typically 0.1 or larger. Higher refractive index differences between the first optical layer and the second optical layer are useful, for example, for providing higher optical power (e.g., reflectivity), which enables more reflective bandwidth. However, in the present disclosure, the absolute difference between the layer pair may be less than 0.20, less than 0.15, less than 0.10, less than 0.05, or even less than 0.03, depending on the layer pair selected.

The thickness of each layer may influence the performance of the optical stack by either changing the amount of reflectivity or shifting the reflectivity wavelength range. The optical layers typically have an average individual layer thickness of about one quarter of the wavelength or wavelengths to be reflected, and a layer pair thickness of about one half of the wavelength or wavelengths to be reflected. The optical layers can each be a quarter-wavelength thick or the optical layers can have different optical thicknesses, as long as the sum of the optical thicknesses for the layer pair is half of a wavelength (or a multiple thereof). For example, to reflect 800 nanometers (nm) light, the average individual layer thickness would be about 200 nm, and the average layer pair thickness would be about 400 nm. First optical layers and second optical layers may have the same thicknesses. Alternatively, the optical stack can include optical layers with different thicknesses to increase the reflective wavelength range. An optical stack having more than two layer pairs can include optical layers with different optical thicknesses to provide reflectivity over a range of wavelengths. For example, an optical stack can include layer pairs that are individually tuned to achieve optimal reflection of normally incident light having particular wavelengths or may include a gradient of layer pair thicknesses to reflect light over a larger bandwidth. The normal reflectivity for a particular layer pair is primarily dependent on the optical thickness of the individual layers, where optical thickness is defined as the product of the actual thickness of the layer times its refractive index. The intensity of light reflected from the optical layer stack is a function of its number of layer pairs and the differences in refractive indices of optical layers in each layer pair. The ratio n₁d₁/(n₁d₁+n₂d₂) (commonly termed the “f-ratio”) correlates with reflectivity of a given layer pair at a specified wavelength. In the f-ratio, n₁ and n₂ are the respective refractive indices at the specified wavelength of the first and second optical layers in a layer pair, and d₁ and d₂ are the respective thicknesses of the first and second optical layers in the layer pair. By proper selection of the refractive indices, optical layer thicknesses, and f-ratio, one can exercise some degree of control over the intensity of first order reflection.

The equation λ/2=n₁d₁+n₂d₂ can be used to tune the optical layers to reflect light of wavelength λ at a normal angle of incidence. At other angles, the optical thickness of the layer pair depends on the distance traveled through the component optical layers (which is larger than the thickness of the layers) and the indices of refraction for at least two of the three optical axes of the optical layer.

The optical stack in the multilayer optical film useful for the visible light-transmitting reflector disclosed herein typically includes all or mostly quarter-wave film stacks. In this case, control of the spectrum requires control of the layer thickness profile in the film stack. Layer thickness profiles of such optical stacks can be adjusted to provide for improved spectral characteristics using the axial rod apparatus taught in U.S. Pat. No. 6,783,349 (Neavin et al.) combined with layer profile information obtained with microscopic techniques.

The basic process for layer thickness profile control involves adjustment of axial rod zone power settings based on the difference of the target layer thickness profile and the measured layer profile. The axial rod power increase needed to adjust the layer thickness values in a given feedblock zone may first be calibrated in terms of watts of heat input per nanometer of resulting thickness change of the layers generated in that heater zone. Fine control of the spectrum is possible using 24 axial rod zones for 275 layers. Once calibrated, the necessary power adjustments can be calculated once given a target profile and a measured profile. The procedure may be repeated until the two profiles converge.

Desirable techniques for providing a multilayer optical film with a controlled spectrum include the use of an axial rod heater control of the layer thickness values of coextruded polymer layers as taught in U.S. Pat. No. 6,783,349 (Neavin et al.); timely layer thickness profile feedback during production from a layer thickness measurement tool (e.g., an atomic force microscope, a transmission electron microscope, or a scanning electron microscope); optical modeling to generate the desired layer thickness profile; and making axial rod adjustments based on the difference between the measured layer profile and the desired layer profile.

The layer thickness profile (layer thickness values) of the optical stack may be adjusted to be approximately a linear profile with the first (thinnest) optical layers adjusted to have about a quarter wave optical thickness (index times physical thickness) for the left band edge of the desired reflection bandwidth and progressing to the thickest layers, which may be adjusted to be about a quarter wave thick optical thickness for the right band edge of the desired reflection bandwidth. In some embodiments, two or more multilayer optical films with different reflection bands are laminated together to broaden the reflection band.

Birefringence (e.g., caused by stretching) of optical layers may increase the difference in refractive index of the optical layers in a layer pair. Optical stacks that include layer pairs, which are oriented in two mutually perpendicular in-plane axes are highly efficient reflectors that capable of reflecting an extraordinarily high percentage of incident light depending on, for example, the number of optical layers, f-ratio, and the indices of refraction.

The reflector in the architectural article disclosed herein transmits visible light. That is, at least a portion of the wavelengths in a range from 400 to 700 nanometers is transmitted. “At least a portion” is meant to comprise not only the entire range of wavelengths between 400 and 700 nanometers, but also a portion of the wavelengths, such as a bandwidth of at least 25 nm, 50 nm, 100 nm, 150 nm or 200 nm. In these embodiments, the transmission may be measured at a normal angle to the multilayer optical film or at a shifted angle of 45 to 60 degrees. In some embodiments, the multilayer optical film has an average visible light transmission of at least 45, 50, 60, 70, 80, 85, 90, 92, or 95 percent at an angle normal to the multilayer optical film. In some embodiments, the multilayer optical film has an average visible light transmission of at least 45, 50, 60, 70, 80, 85, 90, 92, or 95 percent in a wavelength range selected from the group consisting of 400 nanometers to 500 nanometers, 400 nanometers to 600 nanometers, and 400 nanometers to 700 nanometers at a 0 degree angle of incidence (that is, an angle normal to the film).

In many photovoltaic module constructions (e.g., conventional roof-top modules) transmission to visible light is unnecessary. For example, solar backsheets or reflectors on roof tops are often formed on opaque substrates. In some applications, including concentrated photovoltaic applications, it may be considered desirable for a reflector (concentrating mirror) to reflect most of the light usable by photovoltaic cells, which tend to absorb light in the visible range. For example, Int. Pat. App. Pub. No. 2009/140493 (Hebrink et al.) discloses a multilayer film, useful as a solar concentrating mirror, that reflects at least a major portion of the average light across the range of wavelengths that corresponds with the absorption bandwidth of the solar cell onto the solar cell. In contrast, the reflectors of the present disclosure reflect wavelengths in a range that are absorbed by a photovoltaic cell and also transmit visible light that is useful, for example, for daylighting inside a building or structure.

The multilayer optical film in the visible light-transmitting reflector disclosed herein may be designed to switch from transmitting to reflecting in the visible range (e.g., in a range from 600 to 700 nm) or in the infrared range (e.g., in a range from 700 to 900 nm). The wavelength at which the film switches from transmitting to reflecting is called the left band edge. In some embodiments, the multilayer optical film is a color-shifting film. Color-shifting films change color as a function of viewing angle. For example, if the left band edge of the multilayer optical film is about 650 nanometers, against a white background, the film may appear cyan at a zero degree viewing angle and cobalt blue at a shifted viewing angle of 45 to 60 degrees. In another example, if the left band edge of the multilayer optical film is about 720 nanometers, against a white background, the film may appear colorless at a zero degree viewing angle and cyan at a shifted viewing angle of 45 to 60 degrees. For narrow transmission bands (that is, transmission bands in a range of about 100 nm or less), many colors may be seen at successively higher angles of incidence. Further details about color-shifting films may be found, for example, in U.S. Pat. No. 6,531,230 (Weber et al.) and U.S. Pat. No. 6,045,894 (Jonza et al.). Color-shifting films, in addition to providing useful daylighting, may also provide the visible light-transmitting reflector with a unique and attractive appearance.

In the architectural article according to the present disclosure, the visible light-transmitting reflector reflects at least a portion of the light in a range of wavelengths that corresponds with the absorption bandwidth of the photovoltaic cell. “At least a portion” includes bandwidths such as at least 25 nm, 50 nm, 100 nm, 150 nm or 200 nm. Suitable photovoltaic cells include those that have been developed with a variety of semiconductor materials. Each type of semiconductor material will have a characteristic band gap energy which causes it to absorb light most efficiently at certain wavelengths of light, or more precisely, to absorb electromagnetic radiation over a portion of the solar spectrum. Exemplary suitable materials useful for making photovoltaic cells and their photovoltaic light absorption band-edge wavelengths include: a crystalline silicon single junction (about 400 nm to about 1150 nm), amorphous silicon single junction (about 300 nm to about 720 nm), ribbon silicon (about 350 nm to about 1150 nm), copper indium gallium selenide (CIGS) (about 350 nm to about 1100 nm), cadmium telluride (CdTe) (about 400 nm to about 895 nm), and gallium arsenide (GaAs) multi-junction (about 350 nm to about 1750 nm). The photovoltaic cell may also be a bifacial cell or a dye-sensitized cell. In some embodiments, the photovoltaic cell is a crystalline silicon single junction cell, a ribbon silicon cell, a CIGS cell, a GaAs multi-junction cell, or a CdTe cell. In some embodiments, the photovoltaic cell is a crystalline silicon single junction cell, a ribbon silicon cell, a CIGS cell, or a GaAs cell. In some embodiments, the photovoltaic cell is a crystalline silicon single junction cell. New materials suitable for making photovoltaic cells continue to be developed. In some embodiments, the photovoltaic cell is an organic photovoltaic cell. In some of these embodiments, the organic photovoltaic cell is transparent, which may be beneficial to daylighting for the architectural article disclosed herein.

Typically, in the architectural article according to the present disclosure, at least a portion of the light in a range of wavelengths that corresponds with the absorption bandwidth of the photovoltaic cell includes near infrared wavelengths and optionally longer visible wavelengths of light. In some embodiments, the visible light-transmitting reflector according to the present disclosure reflects light in at least a portion of the wavelength range of 650 nm to 1100 nm, 650 nm to 1500 nm, 875 nm to 1100 nm, or 900 nm to 1500 nm. For any of these wavelength ranges, the visible light-transmitting reflector may have an average reflection of at least 30, 40, 50, 60, 70, 80, 90, 95, 97, 98, or 99 percent at a normal angle of incidence. The visible light-transmitting reflector is positioned to reflect the desired bandwidth of light onto the photovoltaic cell. In some embodiments, light outside the range of wavelengths that corresponds with the absorption bandwidth of the photovoltaic cell passes through the visible light-transmitting reflector and is not reflected onto the photovoltaic cell. In other embodiments, some of the light outside the range of wavelengths that corresponds with the absorption bandwidth of the photovoltaic cell is absorbed by the visible light-transmitting reflector, as described below. The selection of multilayer optical films that reflect at least a portion of light in a range of wavelengths that matches selected photovoltaic cells, while reducing radiation adverse to the photovoltaic cell, can significantly enhance the operational efficiency of the photovoltaic cell.

The visible light-transmitting reflector disclosed herein includes first and second optical layers having different indices of refraction. Typically, the first and second optical layers are polymer layers. In this context, the term “polymer” will be understood to include homopolymers and copolymers, as well as polymers or copolymers that may be formed in a miscible blend, for example, by co-extrusion or by reaction, including transesterification. The terms “polymer” and “copolymer” include both random and block copolymers. The polymer in the first optical layer described herein has a higher refractive index than the polymer in the second optical layer. Useful classes of polymers for first optical layers include, in some embodiments, polyesters and polycarbonates.

Polyesters may be derived, for example, from ring-opening addition polymerization of a lactone, or by condensation of a dicarboxylic acid (or derivative thereof such as, for example, a diacid halide or a diester) with a diol. Exemplary dicarboxylic acids include 2,6-naphthalenedicarboxylic acid; terephthalic acid; isophthalic acid; phthalic acid; azelaic acid; adipic acid; sebacic acid; norbornenedicarboxylic acid; bicyclooctanedicarboxylic acid; 1,6-cyclohexanedicarboxylic acid; t-butyl isophthalic acid; trimellitic acid; sodium sulfonated isophthalic acid; 4,4′-biphenyldicarboxylic acid. Acid halides and lower alkyl esters of these acids, such as methyl or ethyl esters may also be used as functional equivalents. The term “lower alkyl” refers, in this context, to alkyl groups having from one to four carbon atoms. Exemplary diols include ethylene glycol; propylene glycol; 1,4-butanediol; 1,6-hexanediol; neopentyl glycol; polyethylene glycol; diethylene glycol; tricyclodecanediol; 1,4-cyclohexanedimethanol; norbornanediol; bicyclooctanediol; trimethylolpropane; pentaerythritol; 1,4-benzenedimethanol; bisphenol A; 1,8-dihydroxybiphenyl; and 1,3-bis(2-hydroxyethoxy)benzene.

In some embodiments, the first optical layer comprises a birefringent polymer. Exemplary polymers useful for forming birefringent optical layers include polyethylene terephthalates (PETs); polyethylene 2,6-naphthalates (PENs); copolyesters derived from naphthalenedicarboxylic acid, an additional dicarboxylic acid, and a diol (coPENs) (e.g., a polyester derived through co-condensation of 90 equivalents of dimethyl naphthalenedicarboxylate, 10 equivalents of dimethyl terephthalate, and 100 equivalents of ethylene glycol); copolyesters derived from terephthalic acid such as those described in U.S. Pat. No. 6,449,093 B2 (Hebrink et al.) or U.S. Pat. App. Publ. No. 2006/0084780 A1 (Hebrink et al.); copolymers of PEN (CoPEN) such as those described in U.S. Pat. No. 6,352,761 (Hebrink et al.) and U.S. Pat. No. 6,449,093 (Hebrink et al.); polyether imides; polyester/non-polyester combinations; polybutylene 2,6-naphthalates (PBNs); modified polyolefin elastomers, thermoplastic elastomers; thermoplastic polyurethanes (TPUs); and syndiotactic polystyrenes (sPSs), which are useful, for example, for their low UV-light absorbance; and combinations thereof.

In some embodiments, the first optical layer comprises an acrylic (e.g., poly(methyl methacrylate) PMMA)), a polyolefin (e.g., polypropylene), a cyclic olefin copolymer, or a combination thereof. Such embodiments may be useful, for example, when the second optical layer comprises a fluoropolymer.

Exemplary specific polymer products that may be useful for the first optical layers include a PET having an inherent viscosity of 0.74 dL/g, available, for example, from Eastman Chemical Company (Kingsport, Term.) and PMMA available, for example, under the trade designations “CP71” and “CP80” from Ineos Acrylics, Inc. (Wilmington, Del.).

The second optical layers of the multilayer optical film can be made, for example, from a variety of polymers. The polymer in the second optical layer may have a glass transition temperature compatible with that of the polymer in the first optical layer. In some embodiments, the polymer in the second optical layer has a refractive index similar to the isotropic refractive index of a birefringent polymer useful for making the first optical layers. Exemplary melt-processible polymers useful in the second optical layers include: polyesters (e.g., polycyclohexanedimethylene terephthalate commercially available from Eastman Chemical Co, Kingsport, Tenn.); polysulfones; polyurethanes; polyamides; polyimides; polycarbonates; polydimethylsiloxanes; polydiorganosiloxane polyoxamide block copolymers (OTPs) such as those described in U.S. Pat. Appln. Publ. Nos. 2007/0148474 A1 (Leir et al.) and 2007/0177272 A1 (Benson et al.); fluoropolymers including homopolymers such as polyvinylidene difluoride (PVDFs), copolymers such as copolymers of tetrafluoroethylene, hexafluoropropylene, and vinylidene fluoride (THVs), copolymers of hexafluoropropylene, tetrafluoroethylene, and ethylene (HTEs); copolymers of tetrafluoroethylene and norbornene; copolymers of ethylene and tetrafluoroethylene (ETFEs); copolymers of ethylene and vinyl acetate (EVAs); copolymers of ethylene and chlorotrifluoroethylene (ECTFEs), fluoroelastomers; acrylics such as PMMA (e.g., that available under the trade designations “CP71” and “CP80” from Ineos Acrylics) and copolymers of methyl methacrylate (coPMMAs) (e.g., a coPMMA made from 75 weight percent methyl methacrylate and 25 weight percent ethyl acrylate (available from Ineos Acrylics, Inc., under trade designations “PERSPEX CP63” and a coPMMA formed from methyl methacrylate and n-butyl methacrylate); styrenic polymers; vinyl acetate copolymers (e.g., ethylene vinyl acetate copolymers); copolymers of ethylene and a cyclic olefin (COCs); blend of PMMA and PVDF (e.g., as available from Solvay Polymers, Inc., Houston, Tex., under the trade designation “SOLEF”); polyolefin copolymers such as poly (ethylene-co-octene) (PE-POs) available from Dow Chemical Co., Midland, Mich., under the trade designation “ENGAGE 8200”, poly (propylene-co-ethylene) (PPPE) available from Fina Oil and Chemical Co., Dallas, Tex. under the trade designation “Z9470”, and a copolymer of atactic polypropylene (aPPs) and isotactic polypropylene (iPPs) available from Huntsman Chemical Corp., Salt Lake City, Utah under the trade designation “REXFLEX W111”; and combinations thereof. Second optical layers can also be made from a functionalized polyolefin such as linear low density polyethylene-g-maleic anhydride (LLDPE-g-MA) (e.g., available from E. I. du Pont de Nemours & Co., Inc., Wilmington, Del. under the trade designation “BYNEL 4105”) or blends of this polymer and others described above.

In some embodiments, polymer compositions suitable for the second optical layers include PMMA, CoPMMA, polydimethyl siloxane oxamide based segmented copolymer (SPDX), fluoropolymers including homopolymers such as PVDF and copolymers such as those derived from tetrafluoroethylene, hexafluoropropylene, and vinylidene fluoride (THVs), blends of PVDF and PMMA, acrylate copolymers, styrene, styrene copolymers, silicone copolymers, polycarbonate, polycarbonate copolymers, polycarbonate blends, blends of polycarbonate and styrene maleic anhydride, and cyclic-olefin copolymers. In some embodiments, the second optical layers comprise poly(methyl methacrylate), copolymers of methyl methacrylate and other acrylate monomers, or blends of poly(methyl methacrylate) and poly(vinylidene difluoride).

The selection of the polymer compositions used in creating the multilayer optical film will depend upon the desired bandwidth that will be reflected onto a chosen photovoltaic cell. Higher refractive index differences between the polymers in the first and the second optical layers create more optical power thus enabling more reflective bandwidth. Alternatively, additional layers may be employed to provide more optical power. Exemplary useful combinations of first and second polymer layers include polyethylene terephthalate with copolymers of tetrafluoroethylene, hexafluoropropylene, and vinylidene fluoride; polyethylene terephthalate with polydimethyl siloxane oxamide based segmented copolymer, polyethylene terephthalate with poly(methyl methacrylate); polyethylene terephthalate with a polyvinylidene difluoride and poly(methyl methacrylate) blend; polyethylene 2,6-naphthalate with copolymers of tetrafluoroethylene, hexafluoropropylene, and vinylidene fluoride; polyethylene 2,6-naphthalate with polydimethyl siloxane oxamide based segmented copolymer; polyethylene 2,6-naphthalate with poly(methyl methacrylate); polyethylene terephthalate with copolymers of methyl methacrylate; polyethylene 2,6-naphthalate with copolymers of methyl methacrylate; copolymers of polyethylene 2,6-naphthalate with poly(methyl methacrylate); copolymers of polyethylene 2,6-naphthalate with polydimethyl siloxane oxamide based segmented copolymer; syndiotactic polystyrene with polydimethyl siloxane oxamide based segmented copolymer; syndiotactic polystyrene with copolymers of tetrafluoroethylene, hexafluoropropylene, and vinylidene fluoride; copolymers of polyethylene 2,6-naphthalate with copolymers of tetrafluoroethylene, hexafluoropropylene, and vinylidene fluoride; polyethylene terephthalate with fluoroelastomers; syndiotactic polystyrene with fluoroelastomers; copolymers of polyethylene 2,6-naphthalate with fluoroelastomers; and poly(methyl methacrylate) with copolymers of tetrafluoroethylene, hexafluoropropylene, and vinylidene fluoride.

Further considerations relating to the selection of materials and manufacturing of optical stacks and multilayer optical films are described in U.S. Pat. No. 5,552,927 (Wheatley et al.); U.S. Pat. No. 5,882,774 (Jonza et al.); U.S. Pat. No. 6,827,886 (Neavin et al.); U.S. Pat. No. 6,830,713 (Hebrink et al.); and U.S. Pat. No. 7,141,297 (Condo et. al.); and in Int. Pat. App. Pub. No. WO 2010/078289 (Hebrink et al.).

In some embodiments, the visible light-transmitting reflector comprises an ultraviolet light-protective layer (UV-protective layer) applied onto at least one surface of the multilayer optical film. In some embodiments, a UV-protective layer may be applied to both surfaces. A UV-protective layer typically shields the multilayer optical film from UV radiation that may cause degradation. In particular the ultraviolet radiation from 280 nm to 400 nm can induce degradation of plastics, which in turn results in color change and deterioration in mechanical properties Inhibition of photo-oxidative degradation is useful for outdoor applications wherein long term durability is desired. The absorption of UV light by polyethylene terephthalates, for example, starts at around 360 nm, increases markedly below 320 nm and is very pronounced at below 300 nm. Polyethylene naphthalates strongly absorb UV light in the 310-370 nm range, with an absorption tail extending to about 410 nm, and with absorption maxima occurring at 352 nm and 337 nm. Chain cleavage occurs in the presence of oxygen, and the predominant photooxidation products are carbon monodioxide, carbon dioxide, and carboxylic acids. Besides the direct photolysis of the ester groups, consideration has to be given to oxidation reactions which likewise form carbon dioxide via peroxide radicals.

Useful UV-protective layers may shield the multilayer optical film by reflecting UV light, absorbing UV light, scattering UV light, or a combination thereof. Useful UV protective layers may include a polymer or combination of polymers that is capable of withstanding UV radiation for an extended period of time while either reflecting, scattering, or absorbing UV radiation. Non-limiting examples of such polymers include poly(methyl methacrylate), silicone thermoplastics, fluoropolymers, and their copolymers, and blends thereof. An exemplary UV-protective layer comprises a blend of poly(methylmethacryate) and polyvinylidene difluoride.

A variety of optional additives may be incorporated into the UV protective layer to assist in its function of protecting the multilayer optical film. Non-limiting examples of the additives include one or more compounds selected from ultraviolet light absorbers, hindered amine light stabilizers, anti-oxidants, and combinations thereof.

UV stabilizers such as UV absorbers are chemical compounds which can intervene in the physical and chemical processes of photo-induced degradation. The photooxidation of polymers from UV radiation can therefore be prevented by use of a protective layer containing UV absorbers to effectively block UV light. UV absorbers are typically included in the UV-absorbing layer in an amount that absorb at least 70 percent, typically 80 percent, more typically greater than 90 percent, or even greater than 99 percent of incident light in a wavelength region from 180 to 400 nm. UV absorbers may be red-shifted UV absorbers, which have enhanced spectral coverage in the long-wave UV region, enabling it to block the high wavelength UV light that can cause yellowing in polyesters. Typical UV-protective layer thicknesses are from 10 microns to 500 microns although thick and thinner UV-absorbing layers can be useful in some applications. Typically, the LTV-absorber is present in the UV-absorbing layer in an amount of from 2 to 20 percent by weight, but lesser and greater levels may also be useful for some applications. In some embodiments, the ultraviolet light protective layer comprises poly(vinylidene difluoride), poly(methyl methacrylate), and an ultraviolet light absorber.

One exemplary UV absorber is a benzotriazole compound, 5-trifluoromethyl-2-(2-hydroxy-3-alpha-cumyl-5-tert-octylphenyl)-2H-benzotriazole. Other exemplary benzotriazoles include 2-(2-hydroxy-3,5-di-alpha-cumylphehyl)-2H-benzotriazole, 5-chloro-2-(2-hydroxy-3-tert-butyl-5-methylphenyl)-2H-benzothiazole, 5-chloro-2-(2-hydroxy-3,5-di-tert-butylphenyl)-2H-benzotriazole, 2-(2-hydroxy-3,5-di-tert-amylphenyl)-2H-benzotriazole, 2-(2-hydroxy-3-alpha-cumyl-5-tert-octylphenyl)-2H-benzotriazole, and 2-(3-tert-butyl-2-hydroxy-5-methylphenyl)-5-chloro-2H-benzotriazole. Additional exemplary UV absorbers include 2-(4,6-diphenyl-1,3,5-triazin-2-yl)-5-hexcyloxyphenol, a diphenyl triazine available under the trade designation “CGXUVA 006” from BASF, Florham Park, N.J.), and those available from Ciba Specialty Chemicals Corp., Tarrytown, N.Y., under the trade designations “TINUVIN 1577” and “TINUVIN 900”. In addition, UV absorber(s) can be used in combination with hindered amine light stabilizer(s) (HALS) and/or antioxidants. Exemplary HALSs include those available from Ciba Specialty Chemicals Corp. under the trade designations “CHIMASSORB 944” and “TINUVIN 123”. Exemplary antioxidants include those available under the trade designations “IRGANOX 1010” and “ULTRANOX 626” from Ciba Specialty Chemicals Corp.

Other additives may be included in the UV-absorbing layer. Small particle non-pigmentary zinc oxide and titanium oxide can also be used as blocking or scattering additives in the UV-absorbing layer. For example, certain nanometer-scale particles can be dispersed in polymer or coating substrates to minimize ultraviolet radiation degradation. The nanoparticles are transparent to visible light while either scattering or absorbing harmful UV radiation thereby reducing damage to thermoplastics. U.S. Pat. No. 5,504,134 (Palmer et al.), for example, describes attenuation of polymer substrate degradation due to ultraviolet radiation through the use of metal oxide particles in a size range of about 0.001 micrometer to about 0.20 micrometer in diameter, and, in some embodiments, from about 0.01 to about 0.15 micrometers in diameter. U.S. Pat. No. 5,876,688 (Laundon) describes a method for producing micronized zinc oxide particles that are small enough to be transparent when incorporated as UV blocking and/or scattering agents in paints, coatings, finishes, plastic articles, and cosmetics. These fine particles such as zinc oxide and titanium oxide with particle size ranged from 10 nm to 100 nm, which can attenuate UV radiation, are commercially available, for example, from Kobo Products, Inc., South Plainfield, N.J. Flame retardants may also be incorporated as an additive in the UV-absorbing layer.

The thickness of the ultraviolet light protective layer is dependent upon an optical density target at specific wavelengths as calculated by the Beer-Lambert Law. In typical embodiments, the ultraviolet light absorbing layer has an optical density greater than 3.5 at 380 nm; greater than 1.7 at 390 nm; and greater than 0.5 at 400 nm. Those of ordinary skill in the art will recognize that the optical densities must remain fairly constant over the extended life of the article in order to provide the intended protective function.

In some embodiments, the ultraviolet light-protective layer is a multilayer ultraviolet light reflective mirror (multilayer UV-reflective mirror). The multilayer UV-reflective mirror is reflective to UV light; for example, it is at least 30, 40, 50, 60, 70, 80, 90, or 95 percent reflective to at least a portion of UV light at a normal angle of incidence. The multilayer ultraviolet light reflective mirror is typically a multilayer optical film that reflects wavelengths of light from about 350 to about 400 nm, or, in some embodiments, from 300 nm to 400 nm. In some embodiments, these wavelengths are included in the absorption bandwidth of the photovoltaic cell. The multilayer ultraviolet light reflective mirror can be made according to the techniques described above for making multilayer optical films except that the polymers for the layer pairs (e.g., third and fourth optical layers in some embodiments), layer thicknesses, and number of layers are selected to reflect UV light. The polymers that make the multilayer optical film are typically selected such that they do not absorb UV light in the 300 nm to 400 nm range. Exemplary suitable pairs of polymers useful for preparing multilayer UV reflective mirrors include polyethylene terephthalate with a tetrafluoroethylene, hexafluoropropylene, and vinylidene fluoride copolymer; poly(methyl methacrylate) with tetrafluoroethylene, hexafluoropropylene, and vinylidene fluoride copolymer; polyethylene terephthalate with SPDX; poly(methyl methacrylate) with SPDX; syndiotactic polystyrene with tetrafluoroethylene, hexafluoropropylene, and vinylidene fluoride copolymer; syndiotactic polystyrene with SPDX; modified polyolefin copolymers (e.g., EVA) with a tetrafluoroethylene, hexafluoropropylene, and vinylidene fluoride copolymer; a thermoplastic polyurethane with a tetrafluoroethylene, hexafluoropropylene, and vinylidene fluoride copolymer; and a thermoplastic polyurethane with SPDX. In some embodiments, a blend of tetrafluoroethylene, hexafluoropropylene, and vinylidene fluoride copolymer obtained under the trade designation “DYNEON THV” (e.g., 220 grade or 2030 grade), from Dyneon LLC, Oakdale, Minn., is employed with PMMA for multilayer LW mirrors reflecting 300-400 nm or with PET for multilayer mirrors reflecting 350-400 nm. In general, 100 to 1000 total layers of the polymer combinations are suitable for use with the present disclosure. Examples of multilayer UV light reflective mirrors can be found, for example, in Int. Pat. App. Pub. No. WO 2010/078105 (Hebrink et al.).

In some embodiments wherein the visible light-transmitting reflector comprises a multilayer UV-reflective mirror, the multilayer UV-reflective mirror comprises a UV absorber, including any of the UV absorbers described above. The UV absorber may be, for example, in one or more of the optical layers or in one or more non-optical skin layers on either side of the optical layer stack of the multilayer UV-reflective mirror.

While UV absorbers, HALS, nanoparticles, flame retardants, and anti-oxidants can be added to a UV protective layer, in other embodiments UV absorbers, HALS, nanoparticles, flame retardants, and anti-oxidants can be added to the multilayer optical layers themselves and/or optional non-optical skin layers or durable top coat layers. Fluorescing molecules and optical brighteners can also be added to a UV protective layer, the multilayer optical layers, an optional durable top coat layer, or a combination thereof.

In some embodiments, including embodiments in which the visible light-transmitting reflector includes a UV protective layer as described in any of the above embodiments, the visible light-transmitting reflector exhibits resistance to degradation by UV light. Resistance to degradation by UV light can be determined using the weathering cycle described in ASTM G155 and a D65 light source operated in the reflected mode. In some embodiments, under the noted test, the visible light-transmitting reflector does not change substantially in color, haze, or transmittance and does not significantly crack, peel, or delaminate. In some embodiments, after exposure of at least 18,700 kJ/m² at 340 nm, the b* value obtained using the CIE L*a*b* scale of the visible light-transmitting reflector increases by 10 or less, 5 or less, 4 or less, 3 or less, or 2 or less. In some embodiments, after exposure of at least 18,700 kJ/m² at 340 nm, the visible light-transmitting reflector exhibits a difference in haze versus the initial haze of up to 20, 15, 10, 5, 2, or 1 percent. In some embodiments, after exposure of at least 18,700 kJ/m² at 340 nm, the visible light-transmitting reflector exhibits a difference in transmission versus the initial transmission of up to 20, 15, 10, 5, 2, or 1 percent.

In some embodiments, including embodiments in which the visible light-transmitting reflector includes a UV-protective layer as described in any of the above embodiments (including embodiments wherein the UV-protective layer is a UV-reflective mirror, the visible light-transmitting reflector remains visible light-transmissive for at least a portion of the visible light spectrum. That is, the UV-protective layer is also at least partially visible light-transmissive.

In some embodiments, the visible light-transmitting reflector may include a layer including infrared absorbing particles to absorb at least some of the infrared light that is not reflected onto the photovoltaic cell. The infrared absorbing particles may be included in some of the optical layers or in non-optical skin layers, for example. The infrared radiation absorbing nanoparticles may include any material that preferentially absorbs infrared radiation. Examples of suitable materials include metal oxides such as tin, antimony, indium and zinc oxides and doped oxides. In some embodiments, the metal oxide nanoparticles include, tin oxide, antimony oxide, indium oxide, indium doped tin oxide, antimony doped indium tin oxide, antinomy tin oxide, antimony doped tin oxide or mixtures thereof. In some embodiments, the metal oxide nanoparticles include antimony oxide (ATO) and/or indium tin oxide (ITO). It may be useful to include infrared absorbing particles, for example, to prevent at least some of the non-reflected infrared light from entering a building or structure into which the architectural article disclosed herein is installed.

In some embodiments, the visible light-transmitting reflector according to the present disclosure includes tie layers, for example, to attach two multilayer optical films with different reflection bandwidths or to attach the multilayer optical film to the UV-protective layer in any of its embodiments. The optional tie layer may facilitate adhesion of the films and provide long term stability while the architectural article of the present disclosure is in use and exposed to outdoor elements.

The optional tie layer may be organic (e.g., a polymeric layer or adhesive), inorganic, or a combination thereof. Exemplary inorganic tie layers include amorphous silica, silicon monoxide, and metal oxides (e.g., tantalum pentoxide, titanium dioxide, and aluminum oxide). The tie layer may be provided by any suitable means, including vapor coating, solvent casting, and powder coating techniques. In some embodiments, the optional tie layer is typically substantially not absorptive of light (e.g., having an absorbance of less than 0.1, less than 0.01, less than 0.001, or less than 0.0001) over the wavelength range of from 400 to 2494 nm. Useful adhesive tie layers include pressure-sensitive adhesives, thermosetting adhesives, hot melt adhesives, and combinations thereof. Exemplary useful adhesive tie layers include optically clear acrylic pressure sensitive adhesives (25 micrometer thickness) available from 3M Company, St. Paul, Minn. as “OPTICALLY CLEAR LAMINATING ADHESIVE 8141” or as “OPTICALLY CLEAR LAMINATING ADHESIVE 8171”; tackified OTP adhesives as described in U.S. Pat. No. 7,371,464 B2 (Sherman et al.); and non-silicone pressure-sensitive adhesives as described, for example, in U.S. Pat. Appl. Pub. No. 2011/0123800 (Sherman et al.). Further examples of tie layers include SPDX, CoPETs including modifications such as with functional groups sulfonic acids, PMMA/PVDF blends, modified olefins with functional comonomers such as maleic anhydride, acrylic acid, methacrylic acid or vinyl acetate. Additionally, UV or thermally curable acrylates, silicones, epoxies, siloxanes, urethane acrylates may be suitable as tie layers. The tie layers may optionally contain UV absorbers as described above and may optionally contain conventional plasticizers, tackifiers, or combinations thereof. The tie layer may be applied utilizing conventional film forming techniques. Since the tie layers are part of the visible light-transmitting reflector, the tie layers are at least partially transmissive to visible light.

In some embodiments, the visible light transmitting reflector according to the present disclosure includes a durable top coat to assist in preventing the premature degradation of the solar concentrating mirror due to exposure to outdoor elements. The durable topcoat is typically abrasion and impact resistant and does not interfere with the reflection of a selected bandwidth of light corresponding to the absorption bandwidth of the photovoltaic cell nor the transmission of visible light. Durable top coat layers may include one or more of the following non-limiting examples, PMMA/PVDF blends, thermoplastic polyurethanes, curable polyurethanes, CoPET, cyclic olefin copolymers (COC's), fluoropolymers and their copolymers such as PVDF, ETFE, FEP, and THV, thermoplastic and curable acrylates, cross-linked acrylates, cross-linked urethane acrylates, cross-linked urethanes, curable or cross-linked polyepoxides, and SPDX. Strippable polypropylene copolymer skins may also be employed. Alternatively, silane silica sol copolymer hard coating can be applied as a durable top coat to improve scratch resistance. The durable top coat may contain UV absorbers, HALS, and anti-oxidants as described above. The visible light-transmitting reflector coated with such a durable top coat is typically thermoformable before the top coat is fully cured at an elevated temperature. The cure temperature depends on the selected materials but may be, for example, 80° C. for 15 to 30 minutes.

A variety of methods may be useful for evaluating the impact or abrasion resistance of the durable top coat. Taber abrasion is one test to determine a film's resistance to abrasion, and resistance to abrasion is defined as the ability of a material to withstand mechanical action such as rubbing, scrapping, or erosion. According to the ASTM D1044 test method, a 500-gram load is placed on top of CS-10 abrader wheel and allowed to spin for 50 revolutions on a 4 square inch test specimen. The reflectivity of the sample before and after the Taber abrasion test is measured, and results are expressed by changes in % reflectivity. In some embodiments, change in % reflectivity is expected to be less than 20%, less than 10%, or less than 5%. Other suitable tests for mechanical durability include break elongation, pencil hardness, sand blast test, and sand shaking abrasion. The durable top coat may also enhance the resistance to weathering of the visible light-transmitting reflector, which may be evaluated by ASTM G155 as described above.

In some embodiments, the visible light-transmitting reflector comprises an antisoiling top coat. In some embodiments, the durable top coat described includes at least one antisoiling component. Examples of antisoiling components include fluoropolymers, silicone polymers, titanium dioxide particles, polyhedral oligomeric silsesquioxanes (e.g., as available as POSS from Hybrid Plastics of Hattiesburg, Miss.), and combinations thereof. In some embodiments, the antisoiling coating may be a hydrophobic coating which includes a polymer matrix (e.g., a silicone or fluoropolymer) and nanoparticles dispersed therein. The nanoparticles may be, for example, polymer (e.g., fluoropolymer) particles, particles of a dielectric material (e.g., silica, alumina, zirconia, titania, or indium tin oxide particles), or metal (e.g., gold) particles. Further details regarding such hydrophobic coatings are described, for example, in Int. Pat. Appl. Pub. Nos. 2012/058090 and 2012/058086, both to Zhang et al., the disclosures of which are incorporated by reference herein. In some embodiments, the antisoiling coating may comprise nanosilica and may be coated out of water. Further details of such coatings are described in Int. Pat. Appl. Pub. Nos. 2012/047867 and 2012/047877, both to Brown et al., the disclosures of which are incorporated by reference herein.

In some embodiments, the architectural article and/or the visible light-transmitting reflector further comprises a visible light-transmitting substrate. The multilayer optical film may be applied to the substrate and optionally the photovoltaic cell may be positioned on a substrate. Although, in some applications, a substrate is not necessary, applying the architectural article disclosed herein onto a substrate may provide additional rigidity or dimensional stability, which may be useful, for example, when the architectural article is installed as part of a building or other structure. Suitable substrates include glass sheets, polymeric sheets, polymer fiber composites, and glass fiber composites. An optional tie layer, such as any of those previously described, may be employed in bonding the architectural article to the substrate. Also, optionally a UV absorber, such as any of those previously described, may be included in the substrate. The architectural article according to the present disclosure may be sandwiched between two substrate layers. One exemplary substrate material is twin wall polycarbonate sheeting, e.g., as available under the trade designation “SUNLITE MULTIWALL POLYCARBONATE SHEET” from Palram Americas, Inc. of Kutztown, Pa. In other embodiments, the architectural article may be sandwiched between two layers of acrylic sheeting, for example, as available under the trade designation “PLEXIGLAS” from Arkema, Inc, Philadelphia, Pa.

Although the substrate onto which at least the visible light-transmitting reflector is applied should let visible light through, it need not be completely transparent. The substrate and the multilayer optical film that form the visible light-transmitting reflector may also be translucent and still allow visible light into a building or other structure, for example. However, the substrate should not be provided with any coating or sheeting that would destroy the visible light-transmitting properties of the reflector. For example, no opaque white, black, or metallic film or paint should be applied on the substrate or the multilayer optical film of the visible light-transmitting reflector.

In some embodiments, the architectural article according to the present disclosure may include a frame (e.g., a window frame) that may enhance its dimensional stability. Additionally, the architectural article or a portion thereof may be reinforced, for example, by injection cladding, corrugation, or addition of ribs, foam spacer layers, or honeycomb structures to improve its dimensional stability.

The visible light-transmitting reflector, and therefore any portion thereof, is typically compliant, which means that the visible light-transmitting reflector is dimensionally stable but pliable enough to enable molding or shaping into various forms. In some embodiments, the materials selected for the visible light-transmitting reflector have less than 10% by weight film formers (crosslinking agents or other multifunctional monomers), based on the total weight of the materials.

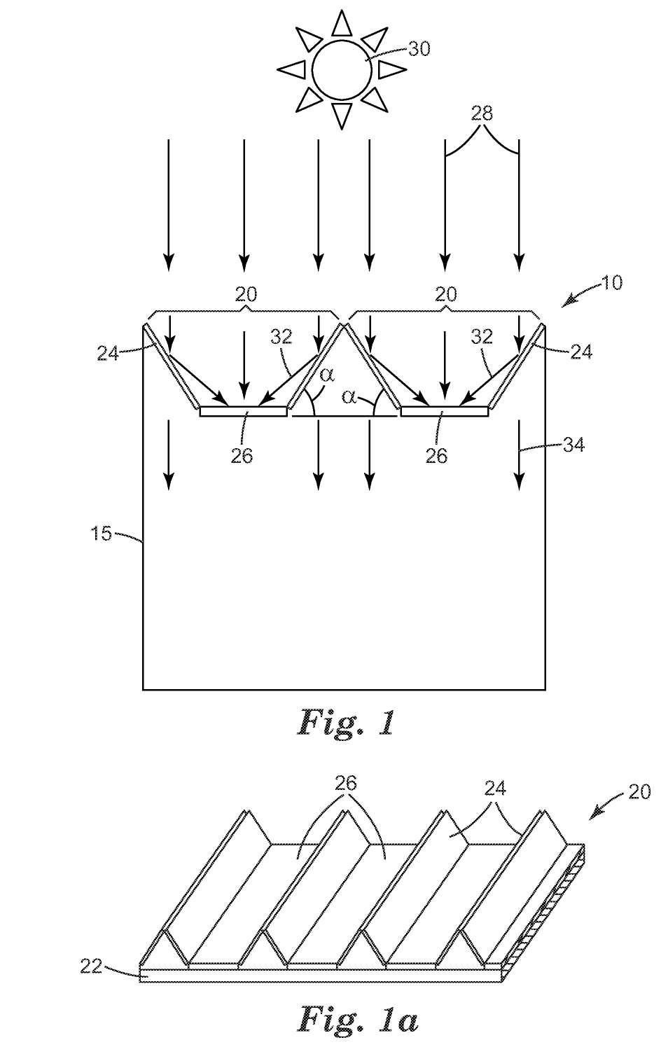

The architectural article according to the present disclosure may be designed to have a variety of sizes, shapes, and configurations of the photovoltaic cell and the visible light-transmitting reflector depending on the desired application. In some embodiments, the visible light-transmitting reflector comprises a multilayer optical film formed into multiple reflective surfaces that reflect onto multiple photovoltaic cells. For example, the visible light-transmitting reflector may be formed into shapes or dimensions conventionally used for solar concentrators (e.g., troughs or parabolic dishes). In some of these embodiments, the multilayer optical film is thermoformed. Thermoforming is generally described in U.S. Pat. No. 6,788,463 (Merrill et al.), herein incorporated by reference in its entirety. The multiple photovoltaic cells and multiple reflective surfaces can be arranged in a variety of ways. Exemplary schematic representations of architectural articles in various configurations 10 are shown in FIGS. 1, 1a, 2, and 3. In each of these illustrated embodiments, photovoltaic cells 26 are positioned in an array (e.g., in a window), and visible light-transmitting reflectors 24 are positioned between the photovoltaic cells 26.

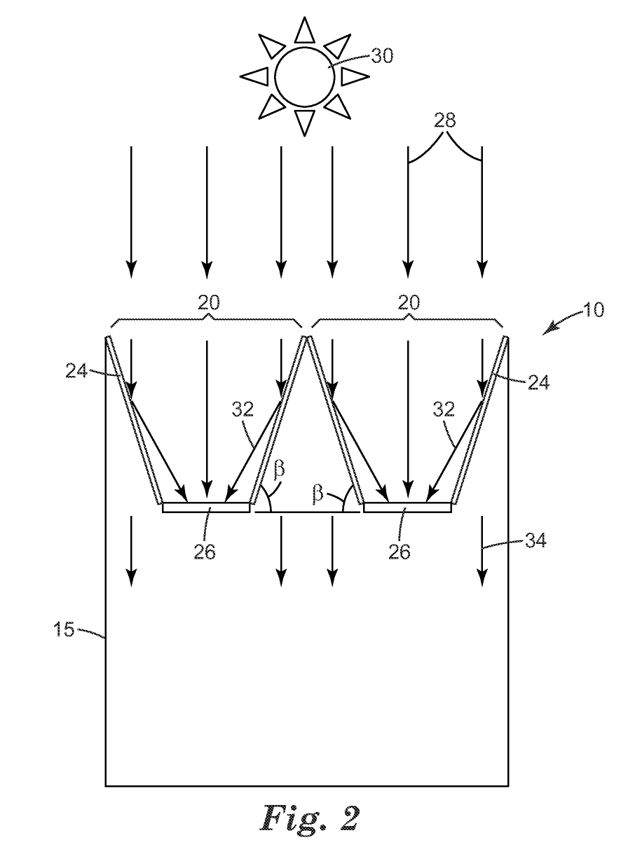

In FIGS. 1, 1a, and 2, the architectural article 20 comprises a multilayer optical film formed into multiple parallel ridges, which form visible light-transmitting reflectors 24, separated by multiple flat areas, with multiple photovoltaic cells 26 located in the flat areas. In some embodiments, the visible light-transmitting reflectors formed by the multilayer optical film are provided only on the multiple parallel ridges and not in the flat areas. In other embodiments, the multilayer film can extend into the flat areas as well. In these embodiments, the visible light-transmitting reflectors 24 reflect from both the sides and back of the photovoltaic cells 26, which may beneficially affect the efficiency of the photovoltaic cells. In the perspective view shown in FIG. 1a, the architectural component 20 further comprises a substrate 22 to which the visible light-transmitting reflectors and the photovoltaic cells are applied. The substrate, which may be any of those described above, may be selected based on the desired application.

In the embodiment illustrated in FIG. 1a, there is a plurality of generally parallel rows of photovoltaic cells 26 positioned on the substrate in an alternating fashion with the visible light-transmitting reflectors 24. The visible light-transmitting reflectors 24 have an elongated shape with two reflective sides. In this manner, a reflector 24 is interposed between each of the adjacent rows of photovoltaic cells 26, and each row of photovoltaic cells is interposed between two reflectors 24. Therefore, in the illustrated embodiment, at least some of the rows (or each row) of photovoltaic cells 26 have two reflectors 24 positioned to reflect light onto them.

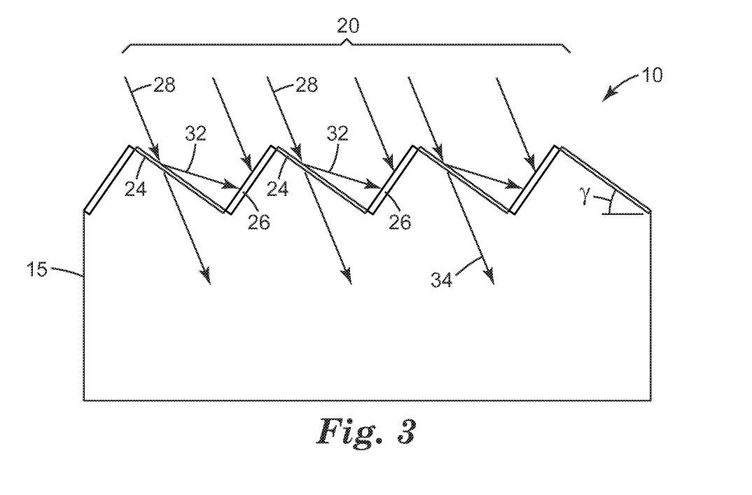

In the embodiment illustrated in FIG. 3, the architectural article further comprises multiple parallel ridges each having first and second opposing ridge faces, wherein the visible light-transmitting reflector 24 is located on each first ridge face, and wherein the photovoltaic cell 26 is located on each second ridge face. In some of these embodiments, the multiple parallel ridges may be formed on a substrate, including any of the substrates mentioned above, and the photovoltaic cells 26 and the visible light-transmitting reflector 24 are positioned on the ridges formed in the substrate. In some embodiments, the multilayer optical film is formed with multiple parallel ridges, and the photovoltaic cells 26 are positioned on the each second ridge face of the multilayer optical film. In these embodiments, the visible light-transmitting reflectors 24 reflect from both the sides and back of the photovoltaic cells 26.

In the schematic drawings shown in FIGS. 1, 2 and 3, the architectural article 20 is shown installed in a building 15 as a roof or other covering for the building. Light 28 from the sun 30 may shine directly on the photovoltaic cells 26 or may shine on the visible light-transmitting reflectors 24, which reflect a portion of the incident light 28 in a range of wavelengths corresponding to the absorption bandwidth of the photovoltaic cells 24. The reflected light 32 can then be absorbed by the photovoltaic cells 24. Visible light 34 is allowed to enter the building 15 through the visible light-transmitting reflectors 24. In some embodiments, the architectural article is integrated into a carport or parking lot roof.

In other embodiments, the architectural article may be positioned inside a building, for example, in proximity to a glass roof top. For example, visible light-transmitting reflectors in the form of parabolic troughs with the photovoltaic cell at the apex of the trough or parabolic dishes positioned to reflect light on a photovoltaic cell may be integrated into a building in a glass atrium.

In addition to advantageously allowing daylighting, the visible light-transmitting reflectors according to the present disclosure can enhance the efficiency of photovoltaic cells due to a reduction in the non-useful bandwidth (e.g., in the infrared) reflected on the cell (e.g., in comparison to broadband reflectors). This reduction in reflected bandwidth helps to minimize the overheating of the photovoltaic cell. Furthermore, the visible light-transmitting reflectors can provide an increased power output that results in lower costs per produced energy (S/Watt). In some embodiments, the power output of the photovoltaic cell is increased by at least 25 (in some embodiments, at least 30, 35, 45, 50, 75, or 100 and up to about 800 to 1000) percent in comparison to an equivalent photovoltaic cell in the absence of any concentrating mirrors. An equivalent photovoltaic cell is one that is made from the same materials and is the same size as the photovoltaic cell in the architectural article disclosed herein.

Further enhancements in photovoltaic cell power output may be achieved when anti-reflective surface structured films or coatings are applied to the front surface of the cell in an architectural article disclosed herein. Surface structures in the films or coating typically change the angle of incidence of light such that it enters the polymer and cell beyond the critical angle and is internally reflected, leading to more absorption by the cell. Such surface structures can be in the shape, for example, of linear prisms, pyramids, cones, or columnar structures. For prisms, typically the apex angle of the prisms is less than 90 degrees (e.g., less than 60 degrees). The refractive index of the surface structured film or coating is typically less than 1.55 (e.g., less than 1.50). These anti-reflective surface structured films or coatings can be made durable and easily cleanable with the use of inherently UV stable and hydrophobic or hydrophilic materials. Durability can be enhanced with the addition of inorganic nano-particles.

The architectural article disclosed herein may be further applied with other conventional solar collection devices. For example, thermal transfer devices may be applied to either collect energy from the photovoltaic cell or dissipate heat from the photovoltaic cell. Conventional thermal heat sinks include thermally conductive materials that include ribs, pins or fins to enhance the surface area for heat transfer. The thermally conductive materials include metals or polymers modified with fillers to improve the thermal conductivity of the polymer. Thermally conductive adhesives (e.g., a thermally conductive adhesive available from 3M Company under the trade designation “3M TC-2810”) may be used to attach photovoltaic cells to thermal transfer devices. Additionally, conventional heat transfer fluids, such as water, oils or fluoroinert heat transfer fluids may be employed as thermal transfer devices.

In some embodiments, the architectural article according to the present disclosure can be placed on celestial tracking devices. At least one of the photovoltaic cell or the visible light-transmitting reflector can be connected to one or more celestial tracking mechanisms. The photovoltaic cell or the visible light-transmitting reflector may be pivotally mounted on a frame. In some embodiments, both the photovoltaic cell or the visible light-transmitting reflector are pivotally mounted on a frame. The pivotally mounted articles may pivot, for example, in one direction or in two directions. In some embodiments, the photovoltaic cell is stationary.

Some useful celestial tracking systems are disclosed in US Pat. App. Pub. No. 2007/0251569 (Shan et al.). These tracking systems allow the visible light-transmitting reflector and the solar cell to pivot in one direction or two directions. In some embodiments, several visible light-transmitting reflectors can be formed as troughs (or other useful shapes such as hyperbolic, elliptical, tubular, or triangular) with photovoltaic cells placed at the axis of the troughs. Two rods are used to connect the troughs to a frame and a crossbar at one or both ends of the assembly. The crossbar can be connected to a driving mechanism. With a plurality of troughs pivotally positioned in a pair of parallel stationary frames, the crossbars to which each trough is attached can, in some embodiments, simultaneously pivot all of the troughs about their axes. Thus, the orientation of all the troughs can be collectively adjusted to follow the sun movement in unison. In some embodiments, the trough is aligned in the east-west direction with a rotational freedom typically not less than 10 degrees, 15 degrees, 20 degrees, or 25 degrees, for example, for adjustments to track the sun through seasonal variations (i.e., through the different paths between equinox and solstice). When the photovoltaic cell is incorporated into a linear compound parabolic concentrator trough tilted toward the south, the incident solar irradiance enters within the acceptance angle of the compound parabolic concentrator. The aperture of the parabola determines how often the position of the trough must be changed (e.g., hourly, daily, or less frequently). In some embodiments, the photovoltaic cell is aligned in the north-south direction, and the rotational freedom is typically not less than 90 degrees, 120 degrees, 160 degrees, or 180 degrees, for example, for tracking adjustments following the sun as it moves across the sky throughout the day. In some of these embodiments, the frame can be mounted, for example, to a back board, which may comprise a mechanism for adjusting tilt to track the sun through seasonal variations.

In other embodiments of architectural articles disclosed herein comprising celestial tracking mechanisms, louvers comprising the visible light-transmitting reflector according to any of the embodiments disclosed herein are pivotally mounted adjacent the photovoltaic cells. A louver can comprise, for example, the visible light-transmitting reflector disclosed herein applied onto a substrate (e.g., a glass sheet, polymeric sheet, a structured polymer sheet comprising a corrugated laminate or a multi-wall polymer sheet construction, or a polymer fiber composite) or a free-standing mirror. In some embodiments, the louver comprises a solar concentrating mirror disclosed herein laminated to a polymer sheet (e.g., PMMA). The louver may be directly attached to either side of the photovoltaic cell (e.g., with hinges), or the louver may be pivotally mounted on a frame that also holds the photovoltaic cell. In some embodiments, there is at least one louver pivotally mounted adjacent each photovoltaic cell. In some embodiments, two louvers are adjacent (in some embodiments, hinged to) each photovoltaic cell. The louvers can track the sun and enable increased capture of sunlight by photovoltaic cells. As a result, typically fewer photovoltaic cells are needed in an array. The louvers typically can move independently with rotational freedom typically not less than 90 degrees, 120 degrees, 160 degrees, or 180 degrees, for example, for tracking adjustments following the sun as it moves across the sky throughout the day. Optionally, the array can be mounted, for example, to one or more frames, which may comprise a mechanism for adjusting tilt to track the sun through seasonal variations. The louvers may be planar, substantially planar, or curved in shape.

Photovoltaic cell arrays with louver solar trackers can be made with a lower profile and lighter weight than typical pole mount trackers. In some embodiments, photovoltaic cells having widths of 1 inch (2.54 cm) or less can be used to minimize the depth profile of the array. Arrays could also be designed with larger photovoltaic cells (e.g., widths of 6-inch (15 cm), 12-inch (30.5 cm), 21-inch (53 cm), or higher). Thus, the arrays can be designed to fit a number of applications including use on roof tops. In embodiments wherein the photovoltaic cells are stationary and the louvers are pivotally mounted, the portion of the electronics connected to the solar cells can also be stationary, which may be advantageous over tracking systems which require movement of the solar cells.

Some useful celestial trackers and louvers described above can be found in FIGS. 7 and 8a-8c of U.S. Pat. App. Pub. No. 2009/0283144 (Hebrink et al.). These figures and their descriptions are herein incorporated by reference.

In some embodiments, when louvers comprise visible light-transmissive reflectors with a low concentration ratio (e.g., less than 10, up to 5, up to 3, up to 2.5, or in a range from 1.1 to 5) the need for expensive and heavy thermal management devices for photovoltaic cells may be reduced. Solar concentration can be adjusted, for example, with the size of the mirror relative to the photovoltaic cell and the mirror's angle relative to the photovoltaic cell to optimize the solar concentration ratio for a desired geographic location. Furthermore, closed loop control systems may be used to adjust the louver position to minimize the concentration ratio such that the photovoltaic cell is maintained below 85° C.

Movement of celestial trackers in any of the above embodiments can be controlled by a number of mechanisms (e.g., piston driven levers, screw driven levers or gears, pulley driven cables, and cam systems). Software can also be integrated with the tracking mechanism based on GPS coordinates to optimize the position of the mirrors.

### Some Embodiments of the Disclosure

In a first embodiment, the present disclosure provides an architectural article comprising:

a photovoltaic cell having an absorption bandwidth; and

a visible light-transmitting reflector positioned to reflect light onto the photovoltaic cell, the visible light-transmitting reflector comprising a multilayer optical film having an optical stack comprising a plurality of alternating first and second optical layers with different indices of refraction, wherein the multilayer optical film reflects at least a portion of light in a range of wavelengths that corresponds with the absorption bandwidth of the photovoltaic cell.

In a second embodiment, the present disclosure provides the architectural article of the first embodiment, wherein the architectural article is installed as part of a building and allows visible light to enter the building through the visible light-transmitting reflector.

In a third embodiment, the present disclosure provides the architectural article of the first or second embodiment, wherein the architectural article is a window, a skylight, or a door.

In a fourth embodiment, the present disclosure provides the architectural article of the first or second embodiment, wherein the architectural article forms at least a portion of a roof. The roof may be on a building, carport, or parking lot, for example.

In a fifth embodiment, the present disclosure provides the architectural article of the first or second embodiment, wherein the architectural article is an awning.

In a sixth embodiment, the present disclosure provides the architectural article of the first or second embodiment, wherein the architectural article is an atrium.

In a seventh embodiment, the present disclosure provides the architectural article of any one of the first to sixth embodiments, wherein the visible light-transmitting reflector has an average visible light transmission of at least 30 percent.

In an eighth embodiment, the present disclosure provides the architectural article of any one of the first to seventh embodiments, wherein the multilayer optical film is a color-shifting film having a left band edge in a range from 600 to 750 nanometers.

In a ninth embodiment, the present disclosure provides the architectural article of any one of the first to eighth embodiments, wherein the multilayer optical film has an average light reflection of at least 50 percent at a normal angle to the multilayer optical film in a wavelength range selected from the group consisting of 650 nanometers to 1100 nanometers, 650 nanometers to 1500 nanometers, 875 nanometers to 1100 nanometers, and 875 nanometers to 1500 nanometers.

In a tenth embodiment, the present disclosure provides the architectural article of any one of the first to ninth embodiments, wherein the photovoltaic cell is crystalline silicon single junction cell, a ribbon silicon cell, a copper indium gallium selenide cell, or a gallium arsenide cell.

In an eleventh embodiment, the present disclosure provides the architectural article of any one of the first to tenth embodiments, wherein the first optical layers comprise polyethylene terephthalate.

In a twelfth embodiment, the present disclosure provides the architectural article of any one of the first to eleventh embodiments, wherein the second optical layers comprise poly(methyl methacrylate), copolymers of methyl methacrylate and other acrylate monomers, or blends of poly(methyl methacrylate) and poly(vinylidene difluoride).

In a thirteenth embodiment, the present disclosure provides the architectural article of any one of the first to twelfth embodiments, further comprising an ultraviolet light protective layer on at least one surface of the visible light-transmitting reflector.

In a fourteenth embodiment, the present disclosure provides the architectural article of the thirteenth embodiment, wherein the ultraviolet light protective layer comprises poly(vinylidene difluoride), poly(methyl methacrylate), and an ultraviolet light absorber.

In a fifteenth embodiment, the present disclosure provides the architectural article of the thirteenth or fourteenth embodiment, wherein the ultraviolet light protective layer is a multilayer ultraviolet light reflective mirror.

In a sixteenth embodiment, the present disclosure provides the architectural article of any one of the first to fifteenth embodiments, further comprising a visible light-transmitting substrate to which at least the multilayer optical film is applied. In some of these embodiments, the architectural article is positioned between two visible light-transmitting substrates.

In a seventeenth embodiment, the present disclosure provides the architectural article of any one of the first to sixteenth embodiments, wherein the multilayer optical film is formed into multiple reflective surfaces that reflect onto multiple photovoltaic cells.

In an eighteenth embodiment, the present disclosure provides the architectural article of any one of the first to seventeenth embodiments, wherein the multilayer optical film is present in multiple parallel ridges separated by multiple land areas, wherein multiple photovoltaic cells are located in the multiple land areas.

In a nineteenth embodiment, the present disclosure provides the architectural article of any one of the first to seventeenth embodiments, further comprising multiple parallel ridges each having first and second opposing ridge faces, wherein the visible light-transmitting reflector is located on each first ridge face, and wherein the photovoltaic cell is located on each second ridge face.

In a twentieth embodiment, the present disclosure provides the architectural article of any one of the first to nineteenth embodiments, further comprising an anti-soiling coating on at least one surface of the visible light-transmitting reflector.

In a twenty-first embodiment, the present disclosure provides the architectural article of any one of the first to nineteenth embodiments, further comprising a scratch-resistant coating on at least one surface of the visible light-transmitting reflector.

In a twenty-second embodiment, the present disclosure provides the architectural article of any one of the first to twenty-first embodiments, wherein the power output of the photovoltaic cell is increased by at least 25 percent in comparison to an equivalent photovoltaic cell in the absence of any concentrating mirrors.

In a twenty-third embodiment, the present disclosure provides the architectural article of any one of the first to twenty-second embodiments, wherein the article transmits at least a portion of infrared light outside the absorption bandwidth of the photovoltaic cell.

In a twenty-fourth embodiment, the present disclosure provides the architectural article of any one of the first to twenty-third embodiments, further comprising a celestial tracking mechanism. In some of these embodiments, the celestial tracking mechanism is building integrated.

In a twenty-fifth embodiment, the present disclosure provides the architectural article of the twenty-fourth embodiment, wherein the celestial tracking mechanism comprises one or more louvers pivotally mounted adjacent the one or more photovoltaic cells, wherein the one or more louvers comprises the visible light-transmitting reflector.

In a twenty-sixth embodiment, the present disclosure provides the architectural article of the twenty-fourth embodiment, wherein at least one of the photovoltaic cell or the visible light-transmitting reflector is pivotally mounted on a frame.

In a twenty-seventh embodiment, the present disclosure provides the architectural article of any one of the twenty-fourth to twenty-sixth embodiments, wherein the photovoltaic cell is stationary.

### EXAMPLES

These examples are merely for illustrative purposes only and are not meant to be limiting on the scope of the appended claims. All parts, percentages, ratios, etc. in the examples and the rest of the specification are by weight, unless noted otherwise. Solvents and other reagents used were obtained from Sigma-Aldrich Chemical Company; Milwaukee, Wis. unless otherwise noted.

### Film Preparations

### Film Preparation 1

A multilayer optical film was made with birefringent layers created from polyethylene terephthalate (PET) (Eastman Chemicals, Kingsport, Term.) and second polymer layers created from a poly(methyl methacrylate) copolymer (CoPMMA) made from 75% by weight methyl methacrylate and 25% by weight of ethyl acrylate (obtained from Atoglas Resin Division, Philadelphia, Pa., under the trade designation “PERSPEX CP63”). PET and CoPMMA were coextruded thru a multilayer polymer melt manifold to create a multilayer melt stream having 550 alternating birefringent layers and second polymer layers. A masterbatch of PET and ultraviolet light absorber (UVA) commercially available under the trade designation “TA07-07MB02” from Sukano, Duncan, S.C. was compounded into the PET optical layers at 10 wt %. In addition, a pair of non-optical polymer blend layers were coextruded as protective skin layers on either side of the optical layer stack. The skin layers were a blend of 35 wt % PVDF (poly(vinylidene difluoride), commercially available from 3M Company, St. Paul, Minn. under the trade designation “3M DYNEON PVDF 6008/0001”, 45 wt % of poly(methyl methacrylate) (PMMA, commercially available under the trade designation “PERSPEX CP82” from Plaskolite, Campton, Calif.) and 20 wt % of a masterbatch PMMA and UVA commercially available under the trade designation “TA11-10MB01” from Sukano. This multilayer coextruded melt stream was cast onto a chilled roll at 22 meters per minute creating a multilayer cast web with optical layers approximately 725 microns (29 mils) thick and a total thickness of 1400 microns. The multilayer cast web was then heated in a tenter oven at 105° C. for 10 seconds before being biaxially oriented to a draw ratio of 3.8 by 3.8. The oriented multilayer film was further heated to 225° C. for 10 seconds to increase crystallinity of the PET layers. Reflectivity of this multilayer near infrared mirror film was measured with a Lambda 950 spectrophotometer resulting in an average reflectivity of 92.5% over a bandwidth of 650 to 1350 nm at normal angles to the film. At a 45 degree angle, the reflectivity of this near infrared mirror film was measured with a Lambda 950 spectrophotometer resulting in an average reflectivity of 94.5% over a bandwidth of 550 to 1250 nm. This near infrared mirror film has a reddish appearance at normal angle and a gold appearance at 45 to 60 degrees off normal angle with a black background behind the mirror. This near infrared mirror film has a cyan appearance at normal angle and a cobalt blue appearance at 45 to 60 degrees off normal angle with a white background behind the mirror. This near infrared mirror film had a light transmission at normal angle to the film of 88% over the visible light wavelengths of 400 to 650 nm.

### Film Preparation 2

A multilayer optical film was made with birefringent layers created from the same PET and the same second polymer layers of CoPMMA as in Film Preparation 1. PET and CoPMMA were coextruded thru a multilayer polymer melt manifold to create a multilayer melt stream having 224 alternating birefringent layers and second polymer layers. In addition, a pair of non-optical PET layers were coextruded as protective skin layers on either side of the optical layer stack. This multilayer coextruded melt stream was cast onto a chilled roll at 22 meters per minute creating a multilayer cast web with a total thickness of approximately 700 microns thick and with a thickness of the optical layer stack of approximately 233 microns. The multilayer cast web was then heated in a tenter oven at 105° C. for 10 seconds before being biaxially oriented to a draw ratio of 3.8 by 3.8. The oriented multilayer film was further heated to 225° C. for 10 seconds to increase crystallinity of the PET layers. Reflectivity of this multilayer near infrared mirror film was measured with a Lambda 950 spectrophotometer resulting in an average reflectivity of 94% over a bandwidth of 875 to 1100 nm at normal angles to the film. At a 45 degree angle, the reflectivity of this near infrared mirror film was measured with a Lambda 950 spectrophotometer resulting in an average reflectivity of 96% over a bandwidth of 750 to 950 nm. In transmitted light, this near infrared mirror film has a clear appearance at normal angle and a clear appearance at 45 to 60 degrees off normal angles. This near infrared mirror film has a light transmission of 88% over the visible light wavelengths of 400 to 700 nm.

### Prophetic Film Preparation 3

A multilayer reflective mirror can be made according to the method described in Film Preparation 1 except with coPMMA of the second polymer layers replaced by the PVDF/PMMA/UVA blend used in the skin layers of Film Preparation 1. The reflectivity measurements of this film would be expected to be higher than those of Film Preparation 1, and the appearance of this film would be expected to be similar to that of Film Preparation 1.

### Prophetic Film Preparation 4

A multilayer mirror film can be made according to the method described in Film Preparation 1 except using oxalylamidopropyl terminated polydimethylsiloxane (produced as described in the first paragraph of the example section of WO2010078105) for the second polymer layers. The multilayer cast web can be heated in a tenter oven at 95° C. before biaxial orientation. The reflectivity measurements and the appearance of this film would be expected to be similar to those of Film Preparation 1. An ultraviolet light protective layer can be made from PMMA (available from Arkema, Inc., Philadelphia, Pa. under the trade designation “VO44”), 5% by weight of an ultraviolet absorber available from CIBA Specialty Chemicals Corp. under the trade designation “TINUVIN 1577”, and 0.15% by weight of a hindered amine light stabilizer available from CIBA Specialty Chemicals Corp. under the trade designation “CHIMASSORB 944” by extrusion compounding. An anhydride-modified ethylene vinyl acetate adhesive available from E. I. DuPont de Nemours & Co., Wilmington, Del., under the trade designation “BYNEL E418” can be extruded as a separate tie layer. The ultraviolet light protective layer can be coated onto the multilayer mirror film and simultaneously directed into a nip under a pressure of 893 kg/m (50 pounds per lineal inch) against a casting tool having a mirror finish surface at a temperature of 90° F., at a casting line speed of 0.38 m/sec (75 feet per minute). The coextrusion coated layers would have a total thickness of 254 microns (10 mils) with skin:tie layer thickness ratio of 20:1. The same coating procedure can be carried out on the opposite side of the multilayer mirror film. The UV absorption band edge of this extrusion coat would have 50% transmission at 410 nm and absorbance of 3.45 at 380 nm.

### Prophetic Film Preparation 5

A multilayer mirror film can be made according to the method described in Film Preparation 1 except using a fluoropolymer available from 3M Company under the trade designation “THV2030” for the second polymer layers. The multilayer cast web can be heated in a tenter oven at 145° C. before biaxial orientation. The reflectivity measurements and the appearance of this film would be expected to be similar to those of Film Preparation 1. An ultraviolet light protective layer as described in Prophetic Film Preparation 4 can be coextrusion coated onto both sides of the multilayer mirror film. The reflectivity measurements of this film would be expected to be higher than those of Film Preparation 1, and the appearance of this film would be expected to be similar to that of Film Preparation 1.

### Prophetic Film Preparation 6

A multilayer reflective mirror can be made according to the method described in Film Preparation 5 except with the ultraviolet light protective layer. The multilayer cast web can be heated in a tenter oven at 95° C. before biaxial orientation. The reflectivity measurements and the appearance of this film would be expected to be similar to those of Film Preparation 1.

### Prophetic Film Preparation 7

A film resulting from any of the Film Preparations 1 to 6 can be laminated to or coextruded with a multilayer UV reflective mirror. This multilayer UV reflective mirror can be made with first optical layers created from PMMA (available from Arkema, Inc., Philadelphia, Pa. under the trade designation “VO44”) and second optical layers created from a fluoropolymer available from 3M Company under the trade designation “3M DYNEON THV2030”. The two polymers can be coextruded thru a multilayer polymer melt manifold to create a multilayer melt stream having 150 alternating birefringent layer and second polymer layers. Additionally, a pair of non-optical layers of PMMA can be coextruded as protective skin layers on either side of the optical layer stack. These PMMA skin layers can be extrusion compounded with 2% by weight of an ultraviolet absorber available from CIBA Specialty Chemicals Corp. under the trade designation “TINUVIN 405”. This multilayer coextruded melt stream can be cast onto a chilled roll at 22 meters per minute creating a multilayer cast web approximately 300 microns (12 mils) thick. The multilayer cast web can then be heated in a tenter oven at 135° C. for 10 seconds prior to being biaxially oriented to a draw ratio of 3.8 by 3.8. The average reflectivity of this multilayer UV mirror film measured with a Lambda 950 spectrophotometer is expected to be 95% over a bandwidth of 350-420 nm.

### Prophetic Film Preparation 8

A film resulting from any of the Film Preparations 1 to 7 can be additionally coated with a thermally cured siloxane, such as a silica-filled methylpolysiloxane polymer available from California Hardcoat Co., Chula Vista, Calif., under the trade designation “PERMA-NEW 6000”. The silica-filled methylpolysiloxane polymer can be applied to films using a Meyer rod with a coating thickness about 3.5 to 6.5 microns. The coating can first be air-dried at room temperature for a few minutes, and then further cured in a conventional oven for 15 to 30 minutes at 80° C.

### Examples 1-6

The films of Film Preparations 1 and 2 were tested at various angles by mounting them in a poly(methyl methacrylate) box at the various angles in Table 1 and configurations shown in FIGS. 1, 2, and 3 with a 2.5 inch by 2.5 inch (6.35 cm by 6.35 cm) monocrystalline silicon photovoltaic cell to simulate a building-integrated photovoltaic (BIPV) assembly. In FIG. 1, the angle α is 60 degrees. In FIG. 2, the angle β is 75 degrees, and in FIG. 3, the angle γ is 35 degrees. The size of the visible light-transmitting reflectors was determined by the following equations:

Wm/Wp=tan(2*Q−90)/[sin(Q)−tan(2*Q−90)*cos(Q)] and

concentration=1+2*(Wm/Wp)*cos(Q),

where Wp is the width of the photovoltaic cell, Wm is the width of the reflector, and Q is the mirror elevation angle.

The BIPV assemblies were irradiated with a 3 KW Custom Collimated Beam Solar Simulator available from ScienceTech of London, Ontario. The ScienceTech solar simulator uses a 3000-watt Osram XBO lamp and an AM1.5D filter to match the solar spectrum. Light from the solar simulator is collimated to +/−0.5 degrees with a Fresnel collimating lens. The irradiation level from the solar simulator was adjusted to 1050 W/m² as measured with a Daystar Meter available from Daystar, Inc. (Las Cruces, New Mexico). Power measurements were made with a handheld Digital Multimeter Model #DM-4400A available from Sperry Instruments (Menominee Falls, Wis.). The results are shown in Table 1, below. For Comparative Example A (CE A), just the photovoltaic cell with no reflectors was evaluated. For configurations described as FIG. 1 and FIG. 2, a double mirror, one on either side of the photovoltaic cell was used. For configurations described as FIG. 3, a single mirror was used.

TABLE 1

| | Film Preparation/ | | | | |
|---|---|---|---|---|---|
| | Configuration | Voc¹ | Isc² | Watts | % Power Increase |
| CE A | No mirrors (Control) | 0.59 | 1.3 | 0.77 | NA |
| Ex. 1 | Film 1/FIG. 1 | 0.58 | 2.1 | 1.22 | 58.8 |
| Ex. 2 | Film 1/FIG. 2 | 0.58 | 2.7 | 1.57 | 104.2 |
| Ex. 3 | Film 1/FIG. 3 | 0.59 | 1.9 | 1.12 | 46.2 |
| Ex. 4 | Film 2/FIG. 1 | 0.58 | 1.96 | 1.14 | 48.2 |
| Ex. 5 | Film 2/FIG. 2 | 0.58 | 2.2 | 1.28 | 66.4 |
| Ex. 6 | Film 2/FIG. 3 | 0.59 | 1.8 | 1.06 | 38.5 |

¹Voc = open circuit voltage;
²Isc = short circuit current

Various modifications and alterations of this disclosure may be made by those skilled in the art without departing from the scope and spirit of this disclosure, and it should be understood that this disclosure is not to be unduly limited to the illustrative embodiments set forth herein.

1. An architectural article comprising:
a photovoltaic cell having an absorption bandwidth; and
a visible light-transmitting reflector positioned to reflect light onto the photovoltaic cell, the visible light-transmitting reflector comprising a multilayer optical film having an optical stack comprising a plurality of alternating first and second optical layers with different indices of refraction, wherein the multilayer optical film reflects at least a portion of light in a range of wavelengths that corresponds with the absorption bandwidth of the photovoltaic cell.

2. The architectural article of claim 1, wherein the architectural article is installed as part of a building and allows visible light to enter the building through the visible light-transmitting reflector.

3. The architectural article of claim 1, wherein the visible light-transmitting reflector has an average visible light transmission of at least 30 percent.

4. The architectural article of claim 1, wherein the multilayer optical film is a color-shifting film having a left band edge in a range from 600 to 750 nanometers.

5. The architectural article of claim 1, wherein the multilayer optical film has an average light reflection of at least 50 percent at a normal angle to the multilayer optical film in a wavelength range selected from the group consisting of 650 nanometers to 1100 nanometers, 650 nanometers to 1500 nanometers, 875 nanometers to 1100 nanometers, and 875 nanometers to 1500 nanometers.

6. The architectural article of claim 1, further comprising an ultraviolet light protective layer on at least one surface of the visible light-transmitting reflector.

7. The architectural article of claim 6, wherein the ultraviolet light protective layer comprises poly(vinylidene difluoride), poly(methyl methacrylate), and an ultraviolet light absorber.

8. The architectural article of claim 6, wherein the ultraviolet light protective layer is a multilayer ultraviolet light reflective mirror.

9. The architectural article of claim 1, further comprising a visible light-transmitting substrate to which at least the multilayer optical film is applied.

10. The architectural article of claim 1, wherein the multilayer optical film is formed into multiple reflective surfaces that reflect onto multiple photovoltaic cells.

11. The architectural article of claim 1, wherein the multilayer optical film is present in multiple parallel ridges separated by multiple land areas, wherein multiple photovoltaic cells are located in the multiple land areas.

12. The architectural article of claim 1, further comprising multiple parallel ridges each having first and second opposing ridge faces, wherein the visible light-transmitting reflector is located on each first ridge face, and wherein the photovoltaic cell is located on each second ridge face.

13. The architectural article of claim 1, further comprising at least one of an anti-soiling or a scratch-resistant coating on at least one surface of the visible light-transmitting reflector.

14. The architectural article of claim 1, wherein the power output of the photovoltaic cell is increased by at least 25 percent in comparison to an equivalent photovoltaic cell in the absence of any concentrating mirrors.

15. The architectural article of claim 1, wherein the photovoltaic cell is a crystalline silicon single junction cell, a ribbon silicon cell, a copper indium gallium selenide cell, or a gallium arsenide cell.

16. The architectural article of claim 1, wherein the architectural article forms at least a portion of a window, a skylight, a door, a roof, an awning, an atrium, a door, or a combination thereof.

17. The architectural article of claim 1, wherein the architectural article forms at least a portion of a roof of a building, carport, or parking lot.

18. The architectural article of claim 1, wherein the first optical layers comprise polyethylene terephthalate, and wherein the second optical layers comprise poly(methyl methacrylate), copolymers of methyl methacrylate and other acrylate monomers, or blends of poly(methyl methacrylate) and poly(vinylidene difluoride).

19. The architectural article of claim 1, wherein the architectural article transmits at least a portion of infrared light outside the absorption bandwidth of the photovoltaic cell.

20. The architectural article of claim 1, further comprising a celestial tracking mechanism.
